(19) United States
(12) Patent Application Publication
(10) Pub. No.: US 2023/0282601 A1
(43) Pub. Date: Sep. 7, 2023

(54) SEMICONDUCTOR JOINING, SEMICONDUCTOR DEVICE

(71) Applicant: FUJI ELECTRIC CO., LTD., Kawasaki-shi (JP)

(72) Inventors: Yoshinori UEZATO, Matsumoto-city (JP); Masanori TAKAZAWA, Matsumoto-city (JP); Shoichiro SAKAI, Matsumoto-city (JP)

(73) Assignee: FUJI ELECTRIC CO., LTD., Kawasaki-shi (JP)

(21) Appl. No.: 18/159,973

(22) Filed: Jan. 26, 2023

(30) Foreign Application Priority Data
Mar. 7, 2022 (JP) 2022-034494

(51) Int. Cl. H01L 23/00; H01L 23/31; H01L 23/29; H01L 21/56

(52) U.S. Cl. CPC H01L 23/564; H01L 21/56; H01L 23/296; H01L 23/3121; H01L 24/29; H01L 24/30; H01L 24/32; H01L 24/45; H01L 24/48; H01L 24/73; H01L 24/83; H01L 24/92; H01L 2224/29139; H01L 2224/30181; H01L 2224/32245; H01L 2224/45124; H01L 2224/48175; H01L 2224/73215; H01L 2224/73265; H01L 2224/83447; H01L 2224/92247

(57) ABSTRACT

The present invention provides a joining that suppresses ion migration and also has excellent corrosion resistance, high bonding strength, and high reliability at the joining, and a semiconductor device. The present invention provides semiconductor joinings comprising: at least two semiconductor constituent members; and silver-containing bonding material layers that bond the semiconductor constituent members, in which a corrosion inhibitor coating layer is provided in contact with the silver-containing bonding material layers, and a semiconductor device including the same.

### CROSS-REFERENCE TO RELATED APPLICATION

This Application claims priority from Japanese Patent Application No. 2022-34494, filed on Mar. 7, 2022, which is incorporated herein by reference in their entirety.

### BACKGROUND OF THE INVENTION

### Field of the Invention

The present invention relates to a semiconductor joining and to a semiconductor device. In particular, the present invention relates to a joining that suppresses electromigration at the joining due to a silver-containing bonding material layer and also has excellent corrosion resistance, high bonding strength, and high reliability, and relates to a semiconductor device.

### DESCRIPTION OF RELATED ART

Power semiconductor modules are widely used in fields in which efficient power conversion is required. For example, application areas are expanding to power electronics fields such as industrial equipment, electric vehicles, and home appliances. These power semiconductor modules have built-in switching elements and diodes, and Si (silicon) semiconductors and SiC (silicon carbide) semiconductors are used for the elements.

As members containing metal such as copper (Cu), conductive connecting members such as lead frames and conductive joining members such as brazing materials and soldering materials have been used in power semiconductor modules. Copper and copper alloys tend to react with oxygen, water, and the like in the air to easily oxidize and corrode. For this reason, a method of forming a coating film of a corrosion inhibitor on the surface of a copper or copper alloy member has been used. As corrosion inhibitors for copper and copper alloys, benzotriazole or derivatives thereof are used and commercially available.

A copper-based lead frame is known in which resin adhesion is ensured by setting the N1s/Cu2p spectrum peak intensity ratio of the X-ray photoelectron spectroscopy analysis value of the surface of a coat film formed by benzotriazole or a derivative thereof formed on a copper or copper alloy surface to a specific range (see, for example, Patent Document 1).

In addition, a technique is known in which a non-benzotriazole-based fatty acid ester-based or amine-based corrosion inhibitor that completely decomposes when heated to around 250° C. and leaves no residue is applied to a base metal lead frame to decompose the corrosion inhibitor prior to the wire bonding and resin sealing steps (see, for example, Patent Document 2).

Furthermore, there is also known a sealing resin composition that has high adhesion to a lead frame on which a corrosion-preventive film is formed using a benzotriazole-based corrosion inhibitor (see, for example, Patent Document 3).

### CITATION LIST

### Patent Documents

Patent Document 1: Japanese Patent Application Publication No. H9-116066
Patent Document 2: Japanese Patent Application Publication No. 2003-197827
Patent Document 3: Japanese Patent Application Publication No. 2010-65160

### SUMMARY OF THE INVENTION

In a laminated substrate that constitutes a semiconductor device (a laminate of a conductive plate and an insulating substrate), in the vicinity of the brazing material that bonds the conductive plate to the insulating substrate, or the bonding material that bonds a semiconductor element and the conductive plate, problems arise such as deterioration in adhesion between these members and the sealing material, and reduction in strength.

In general, the conductive plate made of copper or copper alloy that constitutes the laminated substrate is coated with a benzotriazole-based corrosion inhibitor coating film during the manufacture of the conductive plate, as with the copper lead frames disclosed in Patent Documents 1 to 3. However, as a result of analysis, it has been found that these corrosion-preventive films hardly remain in semiconductor devices after assembly and manufacture. In recent years, corrosion of metal members has become a problem due to the semiconductor module use environment, increased temperature of semiconductor elements, and narrow pitch of metal members such as Cu.

In view of the above analysis results, the present inventors have come to the conclusion that the cause of corrosion lies in the fact that in a corrosive environment such as an H₂S gas atmosphere, sulfur ions easily reach the metal surfaces of the members constituting the semiconductor device, and sulfides are generated and grown. The present inventors have come to the conclusion that, among others, brazing materials containing silver and conductive joining members containing silver particles serve as starting points for migration, and have solved the problem by covering the joinings of these members. Thus, the present invention has been completed.

An embodiment of the present invention is a semiconductor joining including: at least two semiconductor constituent members; and a silver-containing bonding material layer that bonds the semiconductor constituent members, in which a corrosion inhibitor coating layer is provided in contact with the silver-containing bonding material layer.

Preferably, in the above-described semiconductor joining, the corrosion inhibitor is benzotriazole or a derivative thereof, or an amine carboxylate or nitrite.

Preferably, in the above-described semiconductor joining, the silver-containing bonding material layer contains a brazing material, a sintered material, or a soldering material.

Preferably, in the above-described semiconductor joining, the corrosion inhibitor coating layer has a thickness of 1 nm to 10 nm.

Preferably, in the above-described semiconductor joining, at least one of the semiconductor constituent members is a member containing copper or copper alloy, and the corrosion inhibitor coating layer covers the copper or copper alloy.

Preferably, in the above-described semiconductor joining, the at least two semiconductor constituent members are selected from an insulating substrate and a conductive plate, a conductive plate and a semiconductor element, a conductive plate and a heat sink plate, or a semiconductor element and a conductive connecting member.

Another embodiment of the present invention is a semiconductor device including: a semiconductor element that is mounted on a laminated substrate including an insulating substrate and a conductive plate; a sealing material that seals the semiconductor element; and the semiconductor joining.

Preferably, in the above-described semiconductor device, the sealing material contains silicone gel.

Still another embodiment of the present invention is a method of manufacturing a semiconductor device, including: a) bonding a semiconductor element to a laminated substrate that includes an insulating substrate and a conductive plate bonded to the insulating substrate via a first bonding material using a second bonding material; and b) sealing a sealed member including the semiconductor element and the laminated substrate using a sealing material, in which at least one of the first bonding material and the second bonding material is a silver-containing bonding material, and the method includes, after the step a) and before the step b), c) forming a corrosion inhibitor coating layer in contact with a layer of the silver-containing bonding material.

Preferably, in the above-described method of manufacturing a semiconductor device, the first bonding material is a silver-containing bonding material, and the step c) includes forming a corrosion inhibitor coating layer in contact with the layer of the silver-containing bonding material at a joining of the insulating substrate and the conductive plate.

Preferably, in the above-described method of manufacturing a semiconductor device, the second bonding material is a silver-containing bonding material, and the step c) includes forming a corrosion inhibitor coating layer in contact with the layer of the silver-containing bonding material at a joining of the laminated substrate and the semiconductor element.

Preferably, in the above-described method of manufacturing a semiconductor device, the step a) includes bonding a heat sink plate to the laminated substrate using a third bonding material, and the step c) includes forming a corrosion inhibitor coating layer in contact with the layer of the silver-containing bonding material at a joining of the laminated substrate and the heat sink plate.

Preferably, in the above-described method of manufacturing a semiconductor device, the step a) includes bonding a conductive connecting member to the semiconductor element using a fourth bonding material, the fourth bonding material is a silver-containing bonding material, and the step c) includes forming a corrosion inhibitor coating layer in contact with the layer of the silver-containing bonding material at a joining of the semiconductor element and the conductive connecting member.

Preferably, in the above-described method of manufacturing a semiconductor device, the method further includes: a wire bonding step after the step a) and before the step b), and performing the step c) after the wire bonding step and before the step b).

The present invention makes it possible to provide a semiconductor joining that can suppress ion migration and also has excellent corrosion resistance, high bonding strength, and high reliability, and to provide a semiconductor device including the same.

### BRIEF DESCRIPTION OF THE DRAWINGS

FIG. 1 is a conceptual cross-sectional diagram showing the cross-sectional structure of a semiconductor device according to an embodiment of the present invention.

FIG. 2 is an enlarged cross-sectional diagram of portion A of FIG. 1, and is a conceptual cross-sectional diagram showing the cross-sectional structure of a semiconductor joining according to an embodiment of the present invention.

### DESCRIPTION OF PREFERRED EMBODIMENTS

Embodiments of the present invention will be described below with reference to the drawings. Note that the present invention is not limited by the embodiments described below. In addition, in the drawings, some of the members that constitute the device are shown enlarged or reduced in size for the purpose of explanation, and the dimensions of each member and the relative dimensions of multiple members are not intended to limit the present invention.

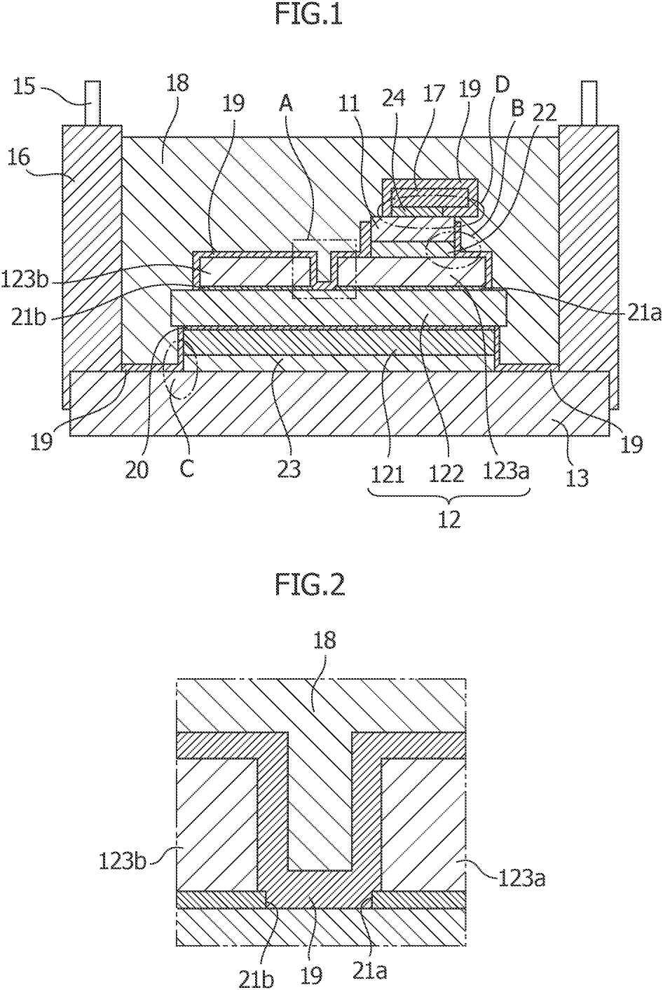

The present invention, according to a first embodiment, relates to a semiconductor joining. Furthermore, according to a second embodiment, the present invention relates to a semiconductor device including the semiconductor joining. First, the configuration of the entire semiconductor device will be described with reference to FIG. 1.

FIG. 1 is a conceptual cross-sectional diagram of a power semiconductor module, which is an example of the semiconductor device according to the second embodiment of the present invention, and FIG. 2 is an enlarged cross-sectional diagram of portion A in FIG. 1. Referring to FIGS. 1 and 2, the power semiconductor module includes a laminated substrate 12 laminated on a heat sink plate 13 via a third bonding material layer 23, and a semiconductor element 11 laminated on the laminated substrate 12 via a second bonding material layer 22. The semiconductor element 11 is bonded with a lead frame 17, which is an example of a conductive connecting member via a fourth bonding material layer 24, and the lead frame 17 is connected to external terminals (not shown), wiring terminals on the laminated substrate, and the like. An external terminal 15 may be connected to the semiconductor element 11 or the like via a conductive connecting member such as an aluminum wire (not shown). A case 16 including a built-in external terminal 15 is adhered to the heat sink plate 13, and the case 16 is filled with a sealing material 18. A corrosion inhibitor coating layer 19 is formed in a manner so as to cover the surfaces of the members forming the joinings in contact with the sealing material 18 at the semiconductor joinings A, B, C, and D.

The semiconductor element 11 is a power chip such as an insulated gate bipolar transistor (IGBT) or a diode chip, or may be a Si device, or may be a wide gap semiconductor device such as a SiC device, a GaN device, a diamond device, or a ZnO device. Also, these devices may be used in combination. For example, a hybrid module using Si-IGBT and SiC-SBD can be used. The number of semiconductor elements to be mounted may be one or more. The semiconductor element 11 includes a back surface electrode bonded to the laminated substrate 12 and a front surface electrode (neither of which is shown).

The laminated substrate 12 can include an insulating substrate 122 and a first conductive plate 121 bonded to one main surface thereof via a first bonding material layer 20, and second conductive plates 123a and 123b bonded to the other main surface by first bonding material layers 21a and 21b. The first bonding material layers 20, 21a, and 21b are all bonding material layers provided in contact with the insulating substrate 122, and are collectively referred to as the first bonding material layer in the present specification. As the insulating substrate 122, a material with excellent electrical insulation and thermal conductivity can be used. Examples of materials for the insulating substrate 122 include Al₂O₃, AlN, and SiN. Particularly for high withstand voltage applications, a material having both electrical insulation and thermal conductivity is preferable, and AlN and SiN can be used, but the material is not limited to these. As the first conductive plate 121 and the second conductive plates 123a and 123b, metal materials such as Cu and Al, which are excellent in workability, can be used. In addition, for the purpose of corrosion prevention, the conductive plate may be made of Cu or Al subjected to a treatment such as Ni plating, or may have a corrosion inhibitor coat film applied during the manufacturing step of the laminated substrate. A conductive plate having a thickness of, for example, approximately 0.15 to 0.8 mm is usually used. As a method of disposing the first conductive plate 121 and the second conductive plates 123a and 123b on the insulating substrate 122, the direct bonding method (direct copper bonding method) or the brazing material bonding method (active metal brazing method) can be mentioned. Note that in a laminated substrate manufactured by the direct bonding method, the first bonding material layers 20, 21a, and 21b may not exist.

In the illustrated embodiment, two second conductive plates 123a and 123b are discontinuously bonded on the insulating substrate 122 via the first bonding material layers 21a and 21b. Specifically, the two second conductive plates 123a and 123b are separated and arranged to expose the insulating substrate 122. The distance (pitch) between the two second conductive plates 123a and 123b may be, for example, approximately 0.5 to 1.5 mm, but is not limited to a specific distance depending on the specifications of the semiconductor device. In general, the narrower the pitch, the greater the risk of short circuiting due to corrosion. However, the corrosion prevention effect can be exhibited even in a semiconductor device having a relatively wide pitch. In addition, in other embodiments, only one second conductive plate may be bonded on the insulating substrate, or three or more second conductive plates may be bonded on the insulating substrate.

In the illustrated embodiment, the lead frame 17 as a conductive connecting member is bonded to the front surface electrode of the semiconductor element 11. The lead frame 17 may be a metal such as copper or an alloy containing copper. A Ni or Ni alloy layer or a Cr or Cr alloy layer may be formed on the surface of the lead frame 17 by a plating method or the like, or it may have a corrosion inhibitor coat film applied during the manufacturing step. In this case, the film thickness of the Ni or Ni alloy layer or the Cr or Cr alloy layer can be approximately 20 µm or less. The lead frame 17 can be bonded to the front surface electrode of the semiconductor element 11 via the fourth bonding material layer 24 made of sintered material, soldering material, or the like. Note that depending on the specifications of the semiconductor device, the lead frame 17 may not exist, but a different conductive connecting member such as a metal wire or metal pin (implant pin) may function similarly.

The heat sink plate 13 is bonded to the first conductive plate 121 via the third bonding material layer 23. As the heat sink plate 13, a metal such as copper or aluminum having excellent thermal conductivity is used. In addition, the heat sink plate 13 may be coated with Ni or Ni alloy to prevent corrosion. The heat sink plate 13 conducts heat generated in the semiconductor element 11 and transmits the heat through the laminated substrate 12 to the cooling device. Note that the heat sink plate 13 itself may be a cooling device.

The case 16 accommodates a sealing material to constitute the outer surface of the semiconductor device. The case 16 may be made of thermoplastic resin such as polyphenylene sulfide (PPS) or polybutylene terephthalate (PBT). Some semiconductor devices have no case, and in such situations, a sealing material made of cured thermosetting resin constitutes the outer surface of the semiconductor device.

The case 16 is filled with a sealing material 18. The sealing material 18 insulates and seals members including the semiconductor element 11, the lead frame 17, the second bonding material layer 22, the third bonding material layer 23, the fourth bonding material layer 24, the corrosion inhibitor coating layer 19, the laminated substrate 12 including the first bonding material layers 20, 21a, and 21b, and the external terminal 15. Note that the sealing material 18 seals the bonding material layer to which the corrosion inhibitor coating layer 19 is applied and other semiconductor constituent members in such a manner that it does not come into contact with these members.

The sealing material 18 is preferably a silicone gel in an aspect. Silicone gel is preferably used because it has a stress relieving effect against vibration and thermal stress and has high insulating properties. However, compared with a sealing material made of thermosetting resin, it has a characteristic of allowing sulfur-containing gases such as H₂S, which may cause corrosion of the silver-containing bonding material, to easily permeate therethrough. Therefore, it can be said that the problem of corrosion is significant in a semiconductor device in which the sealing material 18 is made of silicone gel. The semiconductor joining including a corrosion inhibitor coating layer according to the present invention is particularly advantageous in a semiconductor device in which the sealing material 18 is made of silicone gel. Silicone gel is an organosilicon polymer of which the main chain is composed of siloxane bonds. A silicone polymer having an elastic modulus of 100 MPa or less and a penetration (⅒ mm) of 0.1 to 500 can be preferably used. The sealing material 18 made of silicone gel can be obtained by using organic polysiloxane as a main component, adding a cross-linking agent, a catalyst, and the like, and heat-curing.

In another aspect, the sealing material 18 can be made of a highly heat-resistant thermosetting resin composition. The thermosetting resin composition may contain a thermosetting resin main component, a curing agent, an inorganic filler, and optionally a curing accelerator and an additive.

The thermosetting resin main component is not particularly limited, and examples thereof include epoxy resins, phenol resins, and maleimide resins having heat resistance and high insulation properties. Among them, an epoxy resin having at least two epoxy groups in one molecule is particularly preferable because of its high dimensional stability, water resistance, chemical resistance, and electrical insulation. Specifically, preferable examples used include aliphatic epoxy resins such as bisphenol type A epoxy resins, bisphenol type F epoxy resins, and bisphenol type AD epoxy resins, cycloaliphatic epoxy resins such as monofunctional epoxy resins, difunctional epoxy resins, and trifunctional or higher polyfunctional epoxy resins, and mixtures thereof in any mixing ratio.

The inorganic filler may be a metal oxide or metal nitride with a high thermal conductivity and a small coefficient of linear expansion, and examples thereof include, but are not limited to, fused silica, silica (silicon oxide), alumina, aluminum hydroxide, titania, zirconia, aluminum nitride, talc, clay, mica, and glass fiber. It is preferable to use an inorganic filler having an average particle diameter of approximately 0.2 to 20 µm. The amount of the inorganic filler added to the sealing material 18 is preferably 100 to 600 parts by mass, more preferably 200 to 400 parts by mass, when the mass of the matrix resin is set to 100 parts by mass. If the amount of the inorganic filler blended is less than 100 parts by mass, the coefficient of thermal expansion of the sealing material 18 is high, and peeling and cracking may easily occur. If the amount blended is more than 600 parts by mass, the viscosity of the composition may increase and the extrusion moldability may deteriorate.

The curing agent is not particularly limited as long as it can be cured by reacting with a thermosetting resin base, preferably an epoxy resin main component, but it is preferable to use an acid anhydride-based curing agent. The amount of the curing agent blended is preferably approximately 50 parts by mass or more and 170 parts by mass or less, more preferably approximately 80 parts by mass or more and 150 parts by mass or less, based on 100 parts by mass of the epoxy resin main agent. If the amount of the curing agent is less than 50 parts by mass, the glass transition temperature may decrease due to insufficient cross-linking, and if it is more than 170 parts by mass, the moisture resistance, high heat distortion temperature, and heat resistance stability may deteriorate.

A curing accelerator can be added as an optional component to the thermosetting resin composition that constitutes the sealing material 18. The amount of the curing accelerator is preferably 0.01 parts by mass or more and 50 parts by mass or less, more preferably 0.1 parts by mass or more and 20 parts by mass or less, based on 100 parts by mass of the thermosetting resin main component.

Whether the sealing material 18 is a silicone gel or a thermosetting resin, the sealing material 18 may contain optional additives, as long as properties are not impaired. As additives, for example, flame retardants, pigments for coloring resins, plasticizers, and silicone elastomers for improving crack resistance, and the like can be appropriately added depending on the type of sealing material, but the types of additives are not limited to these. Those skilled in the art can appropriately determine these optional components and the amounts thereof to be added according to the specifications required for either the semiconductor device or the sealing material, or both.

A semiconductor joining according to the first embodiment of the present invention will now be described. The semiconductor joining is formed by at least two semiconductor constituent members and a silver-containing bonding material layer that bonds the semiconductor constituent members; a corrosion inhibitor coating layer is provided in contact with the silver-containing bonding material. Note that in the following description, the semiconductor joining may be abbreviated and simply referred to as a “joining.”

A semiconductor constituent member is a member that constitutes the semiconductor device, and may be any member that can be bonded by the silver-containing bonding material layer. Typically, the semiconductor constituent members may be the members described in FIG. 1 and conductive connecting members (not shown) such as metal wires and metal pins. In some embodiments, one of the at least two semiconductor components may be a member containing copper or copper alloy. Examples of the members containing copper or copper alloy include, but are not limited to, the first conductive plate 121, the second conductive plates 123a and 123b, which are part of the laminated substrate 12, the heat sink plate 13, the lead frame 17, the conductive connecting members such as metal pins, the connection terminals, and the like. The copper or copper alloy portion of a member containing copper or copper alloy can be in contact with the silver-containing bonding material layer to form a joining. The semiconductor constituent members forming a joining are at least two members bonded via the silver-containing bonding material layer, but they may be three or more members.

The silver-containing bonding material layer may be a layer of any bonding material containing silver. Examples of the bonding material containing silver include a brazing material, a sintered material, and a soldering material. The content of silver in the silver-containing bonding material is not particularly limited. For example, it may be a bonding material containing silver to such an extent that it may be corroded by compounds containing water vapor (H₂O) or sulfur (S) atoms, particularly H₂S gas or the like. Examples of the brazing material include silver brazing filler metal. The silver brazing filler metal used is an alloy that contains approximately 40 to 90% by weight of silver and approximately 15 to 40% of copper as well as, optionally, one or two metals selected from titanium (Ti), zinc (Zn), nickel (Ni), tin (Sn), and lithium (Li) and has a liquidus temperature of approximately 620° C. to 800° C. In particular, a brazing material made of Ag—Cu—Ti alloy (Ti content is approximately 1 to 5% by mass) is preferable. The sintered material is, for example, a sintered material that contains silver nanoparticles and/or silver microparticles as well as optionally sintered and integrated particles of gold, copper, nickel, carbon, or the like. These sintered materials are formed by heating and sintering a conductive paste or sheet containing metal particles and a resin binder to form a bonding layer (bonding material layer). The bonding layer can contain 50% by mass or more, preferably 80% by mass or more, of silver. Examples of soldering material include, but are not limited to, Sn—Ag—Cu—based, Sn—Sb—Ag—based, Sn—Sb—Ag—Cu—based, and Sn—Ag—based solder materials. Preferably, Ag is contained in an amount of 1% by mass or more and approximately 20% by mass or less. Note that a bonding material that contains silver only as an unavoidable impurity may be considered as not being a silver-containing bonding material.

The corrosion inhibitor coating layer may be a coating layer that is derived from a corrosion inhibitor and formed by partially forming a chemical bond between a silver-containing bonding material or a metal surface such as copper and the corrosion inhibitor. The corrosion inhibitor may be a commercially available corrosion inhibitor for metals such as copper and silver. Examples include, but are not limited to, benzotriazole (BTA) or derivatives thereof, and amine carboxylates or nitrites. Specific examples usable include, but are not limited to, dicyclohexylammonium nitrite (DICHAN), monoethanolamine benzoate (MEA BA), cyclohexylamine benzoate (CHA BA), dicyclohexylammonium cyclohexane carboxylate (DICHA CHC), cyclohexylamine cyclohexane carboxylate (CHA CHC), dicyclohexylammonium benzoate (DICHA BA), diisopropylammonium benzoate (DIPA BA), dicyclohexylammonium acrylate (DICHA AA), cyclohexylamine acrylate (CHA AA), and dicyclohexylammonium salicylate (DICHA SA). Any commercially available and known corrosion inhibitor with corrosion-inhibiting effect can be used.

FIG. 2 is an example of a semiconductor joining according to the present embodiment, which is a conceptual diagram of joining A composed of second conductive plates 123a and 123b, first bonding material layers 21a and 21b, an insulating substrate 122, and a corrosion inhibitor coating layer 19. In the embodiment shown in FIG. 2, the first bonding material layer 21a is a silver-containing bonding material layer that contacts and bonds the second conductive plate 123a and the insulating substrate 122 together. A corrosion inhibitor coating layer 19 is provided on the surface of the first bonding material layer 21a that is not in contact with the second conductive plate 123a or the insulating substrate 122. It can also be said that such a surface is an exposed surface before sealing and after bonding using the first bonding material layer 21a, in the manufacturing step of the semiconductor device. When the first bonding material layer 21a is a silver-containing bonding material layer, the silver-containing bonding material may typically be a silver brazing filler metal.

Preferably, the corrosion inhibitor coating layer 19 covers the entire exposed surface of the first bonding material layer 21a and is provided in such a manner that the exposed surface does not come into contact with the sealing material 18. This is to prevent contact between sulfur-containing gas or water that can permeate the sealing material 18 and the first bonding material layer 21a. The thickness of the corrosion inhibitor coating layer 19 can be 1 nm to 10 nm, and preferably be 1 nm to 5 nm. If it exceeds 10 nm, the adhesion with the sealing material may deteriorate, and there may be a concern that the insulating properties may deteriorate due to the generation of air bubbles. If it is less than 1 nm, there is a possibility that a sufficient corrosion-inhibiting effect cannot be expected. The thickness of the corrosion inhibitor coating layer 19 may be substantially uniform, or it may vary depending on the location, as long as it is in the range of 1 nm to 10 nm. For example, a relatively thick corrosion inhibitor coating layer 19 can be formed between adjacent conductive plates in which dielectric breakdown is a concern. When one of the semiconductor constituent members, which are joined members in contact with the first bonding material layer 21a, is a member containing copper or copper alloy, the corrosion inhibitor coating layer 19 is preferably provided in such a manner as to cover the entire copper or copper alloy portion of that semiconductor constituent member. This is because members containing copper or copper alloy may also react with gas such as oxygen in the air, water, or the like, and oxidize and corrode easily. Specific examples of the members containing copper or copper alloy in contact with the first bonding material layer 21a include the second conductive plates 123a and 123b. Note that the first bonding material layer 21b in FIG. 2 is similar to the first bonding material layer 21a, and when one of the semiconductor constituent members, which are joined members in contact with the exposed surface of the first bonding material layer 21b and the first bonding material layer 21b, is a member containing copper or copper alloy, the corrosion inhibitor coating layer 19 is preferably provided in such a manner as to cover the entire copper or copper alloy portion of that semiconductor constituent member.

In the embodiment shown in FIGS. 1 and 2, the joining formed by the second conductive plate 123a, the first bonding material layer 21a, and the insulating substrate 122 and the joining formed by the second conductive plate 123b, the first bonding material layer 21b, and the insulating substrate 122 are adjacent to each other. The corrosion inhibitor coating layer 19 is continuously provided in such a manner as to cover the exposed surfaces of the first bonding material layers 21a and 21b and to cover the surfaces of the two second conductive plates 123a and 123b. Furthermore, if the corrosion inhibitor coating layer 19 covers the exposed surfaces of the first bonding material layers 21a and 21b, it may be continuously provided in such a manner as to cover at least part of the opposing sides of the second conductive plates 123a and 123b and the surface of the insulating substrate 122 between the second conductive plate 123a and the second conductive plate 123b. The side surfaces of the second conductive plates 123a and 123b refer to surfaces perpendicular to the thickness direction of the conductive plates. In a semiconductor device, if two or more joinings are located adjacent to each other, it is preferable to provide a continuous single corrosion inhibitor coating layer 19 covering the entire adjacent parts. Here, adjacent means, for example, the case in which the distance between the second conductive plate 123a and the second conductive plate 123b is approximately 1.0 mm or less. If the distance between the second conductive plate 123a and the second conductive plate 123b is short, migration due to corrosion is likely to occur, so that it is preferable to protect the relevant site with the continuous corrosion inhibitor coating layer 19. By continuously covering the opposing side surfaces of the two second conductive plates 123a and 123b with the corrosion inhibitor coating layer 19, it is possible to suppress corrosion in the vicinity of adjacent joinings.

When a sulfur-containing gas or water reaches the bonding material layer, needle-shaped compounds containing sulfides such as silver sulfide (AgS) and copper sulfide (CuS) as main components may be generated. For example, in FIG. 2, when sulfide is generated at the right end of the first bonding material layer 21b, sulfidation of the first bonding material layer 21b causes a decrease in bonding strength, an increase in electrical resistance, and a decrease in dielectric strength. Furthermore, if this sulfide grows further to the right along the insulating substrate 122, the dielectric strength further decreases. Eventually, the grown sulfide may reach the left end of the first bonding material layer 21a. Since sulfide has conductivity, it may cause a short circuit between the first bonding material layers 21a and 21b, resulting in dielectric breakdown. In order to prevent deterioration in performance due to such corrosion, it is preferable to provide a continuous corrosion inhibitor coating layer 19 in the manner shown in FIG. 2. Furthermore, even when the side surfaces of the two second conductive plates 123a and 123b face each other but are not adjacent to each other, the corrosion inhibitor coating layer 19 may cover the exposed surface of the first bonding material layer (21a or 21b). In this case, the corrosion inhibitor coating layer may be continuously provided in such a manner as to cover at least part of the side surfaces of the second conductive plates 123a and 123b and the surface of the insulating substrate 122. The first conductive plate 121 is bonded to the other main surface (back surface) of the insulating substrate 122 via the first bonding material layer 20. Therefore, the corrosion inhibitor coating layer 19 may be provided so as to cover the first bonding material layer 20.

Referring to FIG. 1, other examples of the semiconductor joining include joining B between the second conductive plate 123a, the second bonding material layer 22, and the semiconductor element 11, joining C between the first conductive plate 121, the third bonding material layer 23, and the heat sink plate 13, and joining D between the semiconductor element 11, the fourth bonding material layer 24, and the lead frame 17.

At the semiconductor joining B, the back surface electrode of the semiconductor element 11 and the front surface of the second conductive plate 123a (the surface facing the surface bonded to the insulating substrate 122) are in contact with the second bonding material layer 22. The corrosion inhibitor coating layer 19 is provided in such a manner as to cover the entire exposed surface of the second bonding material layer 22 and the entire surface including the side surface of the second conductive plate 123a. However, the manner of coating with the corrosion inhibitor is not limited to the manner shown. If the corrosion inhibitor coating layer 19 covers the entire exposed surface of the second bonding material layer 22, it may also be formed continuously on a portion of the surface including the side surface of the second conductive plate 123a in contact with the second bonding material layer 22. Alternatively, the corrosion inhibitor coating layer 19 may be formed on a portion of the upper surface of the second conductive plate 123a. However, it is particularly preferable for the corrosion inhibitor coating layer 19 to cover the entire surface including the side surface of the second conductive plate 123a from the viewpoints of improved corrosion resistance and manufacturing efficiency.

Similarly, at the semiconductor joining C, the first conductive plate 121 and the heat sink plate 13 are in contact with the third bonding material layer 23. The corrosion inhibitor coating layer 19 is provided in such a manner as to cover the entire exposed surface of the third bonding material layer 23 and cover the entire surface of the heat sink plate 13. As long as the corrosion inhibitor coating layer 19 covers the entire exposed surface of the third bonding material layer 23, it may be provided continuously in such a manner as to cover the entire exposed surface of the heat sink plate 13 or a portion thereof. Furthermore, if the corrosion inhibitor coating layer 19 covers the entire exposed surface of the third bonding material layer 23, it may be provided continuously in such a manner as to cover the exposed portion of the first conductive plate 121 and the entire exposed surface of the heat sink plate 13 or a portion thereof. The corrosion inhibitor coating layer 19 provided to cover the exposed surface of the third bonding material layer 23 may be provided continuously, reaching the exposed surface of the first bonding material layer 20, or the exposed surfaces of the first bonding material layers 21a and 21b, or even the exposed surface of second bonding material layer 22. Also, the corrosion inhibitor coating layer 19 may be provided in such a manner as to cover the entire exposed surface including the side surface of the insulating substrate 122 or a portion thereof. When the second bonding material layer 22 and the third bonding material layer 23 are silver-containing bonding material layers, the silver-containing bonding material may typically be a silver sintered material or a silver-containing soldering material.

At the semiconductor joining D, the front surface electrode of the semiconductor element 11 and one end of the lead frame 17 are in contact with the fourth bonding material layer 24. The corrosion inhibitor coating layer 19 is provided in such a manner as to cover the entire exposed surface of the fourth bonding material layer 24 and the entire surface of the lead frame 17. Moreover, although not shown, the corrosion inhibitor coating layer 19 may be provided in such a manner as to cover a portion of the lead frame 17 as long as it covers the entire exposed surface of the fourth bonding material layer 24. Furthermore, the corrosion inhibitor coating layer 19 may be continuously provided, reaching the periphery of the semiconductor element 11 in such a manner as to cover a portion or the entire front surface of the semiconductor element 11, as long as it covers the entire exposed surface of the fourth bonding material layer 24. When the fourth bonding material layer 24 is a silver-containing bonding material layer, the silver-containing bonding material may typically be a silver sintered material or a silver-containing soldering material.

Next, a semiconductor device according to a second embodiment of the present invention will be described. A semiconductor device includes a semiconductor element that is mounted on a laminated substrate and a sealing material that seals the semiconductor element, and includes the semiconductor joining described in the first embodiment. A specific structure of the semiconductor device may be the structure illustrated in FIG. 1. Instead of the structure illustrated in FIG. 1, a caseless structure may be used, or a structure may be used in which the heat sink plate is not bonded to the laminated substrate. In the caseless structure, the back surface of the first conductive plate 121 is generally in contact with the sealing material, so that from the viewpoint of adhesion with the sealing material, it may be preferable not to provide the corrosion inhibitor coating layer on the back surface of the first conductive plate 121. Alternatively, a structure may be employed in which a printed circuit board is connected to the front surface electrode of the semiconductor element with a metal pin without providing a lead frame. As the printed circuit board, it is possible to use a polyimide film substrate or an epoxy film substrate on which a conductive layer such as Cu or Al is formed. A copper pin using copper can be used as the metal pin. Both the conductive layer of the printed circuit board and the metal pin may be made of Cu or Al subjected to a treatment such as Ni plating for the purpose of corrosion prevention or the like. The printed circuit board and metal pins can electrically connect semiconductor elements to each other or a semiconductor element with the laminated substrate. The metal pin and the laminated substrate or semiconductor element can be bonded with a sintered material or a soldering material. In addition, the metal pin can be used as an external connection terminal by extending the metal pin from the laminated substrate to the outside of the sealing material.

The semiconductor device according to the second embodiment includes at least one semiconductor joining described in the first embodiment. The semiconductor device illustrated in FIG. 1 includes semiconductor joinings A, B, C, and D, and the semiconductor device according to the second embodiment includes any one or more of these. If the first bonding material layers 20, 21a, and 21b, the second bonding material layer 22, the third bonding material layer 23, or the fourth bonding material layer 24 is not a silver-containing bonding material layer, the joining provided with that bonding material layer does not correspond to the semiconductor joining according to the first embodiment. This is because, depending on the specifications of the semiconductor device, it may be preferable to form a bonding material layer using a silver-free bonding material, and the first bonding material layers 20, 21a, and 21b may not exist. It is also possible to optionally provide a corrosion inhibitor coating layer at a joining in which a bonding material layer is formed using a silver-free bonding material, such as a joining made of a bonding material layer containing copper, making it possible to prevent corrosion.

In the semiconductor device according to the second embodiment, if at least two silver-containing bonding material layers are positioned close to each other, as in joining A shown in FIG. 2, it is preferable to form a corrosion inhibitor coating layer also on an insulating member between the two silver-containing bonding material layers so that the corrosion inhibitor coating layer is positioned between the two silver-containing bonding material layers. This is to prevent dielectric breakdown due to a decrease in dielectric strength.

Optionally, the semiconductor device according to the second embodiment may be provided with a primer layer such as polyimide or polyamide-imide between the sealed member and the sealing material 18. In that case, it is preferable to provide a primer layer at a site in which the corrosion inhibitor coating layer is not formed. This is because if a primer layer is provided on top of or under the corrosion inhibitor coating layer, the adhesion between the primer layer or the corrosion inhibitor coating layer and the sealing material layer may deteriorate, resulting in a decrease in corrosion resistance or insulation.

Next, the semiconductor device according to the second embodiment will be described from the viewpoint of the manufacturing method. A method for manufacturing a semiconductor device according to the second embodiment includes the steps of:
a) bonding a semiconductor element to a laminated substrate that includes an insulating substrate and a conductive plate bonded to the insulating substrate via a first bonding material using a second bonding material; and
b) sealing a sealed member including the semiconductor element and the conductive connecting member using a sealing material,
   at least one of the first bonding material and the second bonding material is a silver-containing bonding material, and
   the method includes, after the step a) and before the step b),
c) forming a corrosion inhibitor coating layer in contact with the silver-containing bonding material.

In step a), a semiconductor element is bonded to the laminated substrate 12 using a second bonding material. The laminated substrate 12 can be prepared by bonding the first conductive plate 121 to one main surface of the insulating substrate 122 and the second conductive plates 123a and 123b to the other main surface using a first bonding material. The first bonding material may typically be a brazing material, or it may be the silver brazing filler metal described as a component of the first bonding material layers 20, 21a, and 21b in the second embodiment, or it may be other brazing material. The second bonding material may typically be a sintered material or a soldering material, or may be the silver sintered material or the silver-containing soldering material described as a component of the second bonding material layer 22 in the first embodiment.

In manufacturing a semiconductor device having a heat sink plate 13, a step of bonding the heat sink plate and the first conductive plate 121 using a third bonding material can be performed in step a). The third bonding material may typically be a sintered material or a soldering material, and may be the silver sintered material or the silver-containing soldering material described as a component of the third bonding material layer 23 in the first embodiment. In the case of the silver sintered material or the silver-containing soldering material described as a component of the third bonding material layer 23, it is preferable to form the corrosion inhibitor coating layer 19 by step c). Moreover, if a lead frame or a metal pin is bonded to the front surface electrode of the semiconductor element 11 as a conductive connecting member, it is preferable to perform it in step a). Here, the bonding material for bonding a lead frame and a metal pin may be the silver sintered material or the silver-containing soldering material described as a component of the fourth bonding material layer 24 in the first embodiment. In the case of the silver sintered material or the silver-containing soldering material described as a component of the fourth bonding material layer 24, it is preferable to form the corrosion inhibitor coating layer 19 by step c).

The bonding temperature in step a) may be higher than approximately 200° C. and up to approximately 350° C., depending on the type of bonding material.

As an optional step, in a semiconductor device including a case, a step of adhering a case 16 to the heat sink plate 13 can be performed after step a) and before step b). Adhesion can be performed with an adhesive such as a thermosetting resin.

As an optional step, a wire bonding step may be performed between steps a) and b). Wire bonding typically uses conductive connecting members such as aluminum wires to connect between the semiconductor element 11 and the second conductive plate 123b, between the semiconductor element 11 and the external terminal, between the conductive plate and the external terminal, and/or between multiple conductive plates.

Step b) is a sealing step with the sealing material 18. When sealing with a sealing material containing a thermoplastic resin such as silicone gel, it is preferable to inject silicone gel into the case 16 and heat it at 100 to 150° C. for 0.5 to 2 hours. On the other hand, if sealing is performed using a sealing material containing a thermosetting resin such as epoxy resin, the thermosetting resin composition constituting the sealing material is injected into the case 16 and is heat-cured. The heat-curing step can be, for example, two-stage curing, and if an epoxy resin is used as the thermosetting resin main component, it can also be performed in three stages by heating at 80 to 120° C. for 1 to 2 hours, 120 to 160° C. for 1 to 2 hours, and 170 to 190° C. for 1 to 2 hours. However, it is not limited to any particular temperature or time, and in some cases, it may be unnecessary to have a two-stage or three-stage curing. In the manufacture of a semiconductor device without a case, the sealed member which has been assembled in step b) and provided with a corrosion inhibitor coating layer can be placed in an appropriate mold, and the mold can be filled with a sealing material for heat-curing. Such sealing methods include vacuum casting, transfer molding, and liquid transfer molding, but are not limited to specific methods. Note that in step b), the corrosion inhibitor coating layer 19 is heated at less than 200° C. while being covered with the sealing material, but the corrosion inhibitor coating layer 19 itself does not disappear.

Step c) of forming the corrosion inhibitor coating layer 19 is performed by attaching a corrosion inhibitor to the exposed surface of the bonding material layer made of silver-containing bonding material. Step c) is performed after step a) and before step b). When the case bonding step is performed, step c) may be performed before or after the bonding step. Note that it is preferable not to include a step in which the temperature exceeds 200° C. between step b) and step c). In step a), when forming the second bonding material layer, the third bonding material layer, or the fourth bonding material layer, there might be a step in which the temperature exceeds 200° C. For this reason, if step c) is performed after step a), the corrosion inhibitor coating layer is not exposed to high temperatures exceeding 200° C., making it possible to suppress deterioration of the corrosion preventive functions due to decomposition or alteration of the corrosion inhibitor coating layer. Also, if wire bonding is performed as an optional step, step c) is preferably performed after wire bonding. This is to prevent the corrosion inhibitor coating layer from being affected by heat or the like due to wire bonding.

It is possible to form a corrosion inhibitor coating layer by a spraying method of spraying a solution containing a corrosion inhibitor, an immersion method of immersing an assembly of members manufactured in the previous steps in a solution containing a corrosion inhibitor, or a coating method using a dispenser. In any method, a solution is prepared by diluting the corrosion inhibitor with a solvent such as isopropyl alcohol or methanol. The concentration of the solution is preferably adjusted according to the desired film thickness, and in order to obtain the preferable film thickness of 1 to 10 nm mentioned above, the concentration of the corrosion inhibitor can be approximately 1 to 10% by mass. Conditions such as concentration and coating amount for forming a desired film thickness can be determined by preliminary experiments. For example, if a corrosion inhibitor coating layer is formed on a copper plate or a ceramic plate under varying film forming conditions, and the film thickness is measured with an atomic force microscope (AFM), it is possible to obtain the relationship between the film formation conditions and the film thickness, determining the film formation conditions. The spraying method and immersion method are preferably performed, for example, under temperature conditions of approximately 50 to 70° C. for approximately 30 seconds or longer. Furthermore, in the case of the spraying method and immersion method, it is possible to mask the sites in which it is unpreferable to attach the corrosion inhibitor and the periphery thereof, but they can also be performed without masking. Masking can be performed by attaching a film or forming a resist layer. In the coating method, a dispenser is used to coat a predetermined site with a diluted solution of the corrosion inhibitor. After spraying, dipping, and coating, it is preferably dried at approximately 70 to 90° C. for approximately 5 to 20 minutes. Before sealing, the thickness of the formed corrosion inhibitor coating layer can be evaluated using an AFM from the level difference between the formed portion of the corrosion inhibitor coating layer and the untreated portion. Surface analysis by X-ray photoelectron analysis (ESCA) also makes it possible to estimate the thickness of the corrosion inhibitor coating layer from the depth at which the elements constituting the corrosion inhibitor are present. In the semiconductor device after sealing, the thickness of the corrosion inhibitor coating layer can be evaluated by performing cross-sectional measurement with a scanning electron microscope (SEM) at a site including the cross section of the thickness of the corrosion inhibitor coating layer.

The semiconductor device including the semiconductor element joining according to the present embodiment, if manufactured by the above-described manufacturing method, it is possible to manufacture a highly reliable semiconductor device having excellent corrosion resistance and joining strength without causing deterioration in corrosion preventive performance due to vaporization of the corrosion inhibitor coating layer or the like. Examples

The present invention will be described in more detail below with reference to Examples of the present invention. However, the present invention is not limited to the scope of the following examples.

### Manufacture of Power Semiconductor Test Module

The power semiconductor test module shown in FIG. 1 was manufactured. The test module used was a MOSFET module with semiconductor joining A only, and the laminated substrate 12 had conductive plates 121, 123a, and 123b made of copper foil bonded to a ceramic insulating substrate 122 via the first bonding material layers 21a and 21b each having a thickness of approximately 15 µm and made of silver brazing filler metal (Ag 80%, Cu 20%). The step of forming a corrosion inhibitor coating layer was performed by coating a corrosion inhibitor solution using a dispenser after the wire bonding step and before the sealing step. The temperature in the step of forming a corrosion inhibitor coating layer was set at 60° C., and after coating, it was dried at 80° C. for 10 minutes. A silicone gel was used as the sealing material and heated at 150° C. for 1 hour. The lid of the exterior case, not shown in FIG. 1, was of the fitting type. In other words, the structure was such that outside air could enter. No primer was used because there was a possibility that a primer, if provided on the surface of the sealed member, could deteriorate the corrosion resistance. Example 4 evaluated the joining in which the second conductive plate 123a made of copper foil was bonded to the back electrode of the semiconductor element 11 via the second bonding material layer 22 formed of an Ag sintered body and having a thickness of 100 µm. A sheet material of Ag nanoparticles was used as the Ag sintered body. The sheet material was arranged at a location corresponding to under the semiconductor element on the conductive plate, and then the semiconductor element was placed on the sheet material and was sintered by heating at 250° C. for 5 minutes under a pressure of 10 MPa to form a joining.

The thickness of the corrosion inhibitor coating layer was evaluated by coating a flat portion (copper foil or ceramic surface) with the corrosion inhibitor solution using a dispenser and measuring the thickness from the level difference between the coated portion and the non-coated portion using AFM. The thickness of the corrosion inhibitor coating layer was adjusted by the concentration of the corrosion inhibitor solution.

Corrosion resistance was evaluated by performing a corrosive gas exposure test on the test module. As the corrosive gas, 10 ppm hydrogen sulfide gas (H₂S) was used, and the test module was exposed at 40° C. and 80% RH for 1000 hours. After the exposure, the corrosion product between the second conductive plates 123a and 123b (hereinafter also referred to as between Cu—Cu) was observed with an optical microscope at a magnification of 300 to measure the length of the corrosion product. Note that the Cu—Cu distance was aimed at 0.8 mm. However, in Example 4, the corrosion product on the side surface of the second bonding material layer 22 (hereinafter also referred to as the Ag sintered body) made of silver-containing bonding material was checked for the presence or absence of sulfide by cross-sectional composition analysis, and was observed with an optical microscope at a magnification of 300 to measure the length (size) of the corrosion product in a similar manner. Note that the length (size) of the corrosion product was defined as the maximum length of the corrosion product in the microscopic observation images. The corrosion product is a sulfide that can be identified by cross-sectional composition analysis or the like, and it can be distinguished from the characteristic that they grow like dendrites or whiskers from the edges of the conductive plate (Cu) and the bonding material layer. As for the evaluation criteria, the determination was “D” if the length of the corrosion product exceeded 100 µm, as “C” if it was 50 to 100 µm, “B” if it was greater than 0 and less than 50 µm, and “A” if no corrosion product was observed. Note that even when the evaluation was “C”, it was confirmed that dielectric breakdown or the like due to migration did not occur and there was no problem in functioning as a module.

Table 1 shows the results. Note that the types of corrosion inhibitors are indicated by abbreviated names, but the formal names are as described above.

TABLE 1

| | | | | |
|---|---|---|---|---|
| | Corrosion Inhibitor | Corrosion Evaluation Site | Corrosion Inhibitor Coating Layer Thickness | Evaluation |
| Example 1 | BTA | Between Cu—Cu | 1 nm | C |
| Example 2 | BTA | Between Cu—Cu | 2 nm | A |
| Example 3 | BTA | Between Cu—Cu | 5 nm | A |
| Example 4 | BTA | Side Surface of Ag Sintered Body | 2 nm | B |
| Example 5 | BTA | Between Cu—Cu | 15 nm | C |
| Comparative Example 1 | None | Between Cu—Cu | 0 nm | D |

Next, the types of corrosion inhibitors were changed to evaluate the corrosion resistance effects. Table 2 shows the results.

TABLE 2

| | | | | |
|---|---|---|---|---|
| | Corrosion Inhibitor | Corrosion Evaluation Site | Corrosion Inhibitor Coating Layer Thickness | Evaluation |
| Example 2 | BTA | Between Cu—Cu | 2 nm | A |
| Example 10 | DICAN | Between Cu—Cu | 2 nm | B |
| Example 11 | MEA BA | Between Cu—Cu | 2 nm | B |
| Example 12 | DICHA BA | Between Cu—Cu | 2 nm | C |
| Example 13 | DIPA BA | Between Cu—Cu | 2 nm | C |
| Example 14 | CHA BA | Between Cu—Cu | 2 nm | B |
| Example 15 | DICHA CHC | Between Cu—Cu | 2 nm | B |
| Example 16 | CHA CHC | Between Cu—Cu | 2 nm | B |
| Example 17 | DICHA AA | Between Cu—Cu | 2 nm | B |
| Example 18 | CHA AA | Between Cu—Cu | 2 nm | B |

It could be confirmed from Tables 1 and 2 that, in the case of using any of the corrosion inhibitors of the Examples, the formation of a corrosion inhibitor coating layer suppressed the growth of corrosion products compared to the case of not forming a corrosion inhibitor coating layer, meaning that a highly reliable joining had been formed.

Reference Example: Detection of Corrosion Inhibitor Coating Layer by X-Ray Photoelectron Analysis (ESCA)

Reference Example 1 was a sample in which BTA was applied as a corrosion inhibitor to the copper surface to form a 2 nm thick corrosion inhibitor coating layer, and Reference Example 2 was a copper plate sample in which no corrosion inhibitor coating layer was formed. The outermost surface of each sample was analyzed by ESCA to obtain a semiquantitative value of the surface composition ratio. Table 3 shows the results. The unit of numerical values in the table is atomic % (at%). For each sample, the results for two different surface composition ratios are shown in the Table. As a result of measuring the composition ratio at a depth of 10 nm from the outermost surface, in Reference Example 1, the nitrogen (N) component was detected up to a depth of approximately 2 nm from the outermost surface, and it was confirmed that the ratio of the nitrogen (N) component did not decrease. From this, the thickness of the corrosion inhibitor coating layer could be estimated to be approximately 1 to 2 nm. From the Reference Examples, it was confirmed that the thickness of the corrosion inhibitor coating layer before sealing could be analyzed and evaluated by ESCA.

TABLE 3

| | C | N | O | Ag | Cu |
|---|---|---|---|---|---|
| Reference Example 1 With corrosion inhibitor coating layer (BTA) | 73.3 | 14.4 | 4.4 | - | 7.9 |
| | 74.5 | 14.4 | 3.5 | - | 7.6 |
| Reference Example 2 Without corrosion inhibitor | 25.5 | - | 29.7 | 1.4 | 43.4 |
| | 23.1 | - | 31.2 | 2.5 | 43.2 |

REFERENCE SIGNS LIST

| | |
|---|---|
| 11 | semiconductor element |
| 12 | laminated substrate |
| 121 | first conductive plate |
| 122 | insulating substrate |
| 123a, 123b | second conductive plate |
| 13 | heat sink plate |
| 15 | external terminal |
| 16 | case |
| 17 | lead frame |
| 18 | sealing material |
| 19 | corrosion inhibitor coating layer |
| 20, 21a, 21b | first bonding material layer |
| 22 | second bonding material layer |
| 23 | third bonding material layer |
| 24 | fourth bonding material layer |
| A, B, C, D | semiconductor joining |

What is claimed is:

1. A semiconductor joining comprising:
at least two semiconductor constituent members; and
a silver-containing bonding material layer that bonds the semiconductor constituent members,
wherein a corrosion inhibitor coating layer is provided in contact with the silver-containing bonding material layer.

2. The semiconductor joining according to claim 1, wherein the corrosion inhibitor is benzotriazole or a derivative thereof, or an amine carboxylate or nitrite.

3. The semiconductor joining according to claim 1, wherein the silver-containing bonding material layer contains a brazing material, a sintered material, or a soldering material.

4. The semiconductor joining according to claim 1, wherein the corrosion inhibitor coating layer has a thickness of 1 nm to 10 nm.

5. The semiconductor joining according to claim 1, wherein at least one of the semiconductor constituent members is a member containing copper or copper alloy, and the corrosion inhibitor coating layer covers the copper or copper alloy.

6. The semiconductor joining according to claim 1, wherein the at least two semiconductor constituent members are selected from an insulating substrate and a conductive plate, a conductive plate and a semiconductor element, a conductive plate and a heat sink plate, or a semiconductor element and a conductive connecting member.

7. A semiconductor device comprising:
a semiconductor element mounted on a laminated substrate including an insulating substrate and a conductive plate;
a sealing material that seals the semiconductor element; and
the semiconductor joining according to claim 1.

8. The semiconductor device according to claim 7, wherein the sealing material contains silicone gel.

9. A method of manufacturing a semiconductor device, comprising:
a) bonding a semiconductor element to a laminated substrate that includes an insulating substrate and a conductive plate bonded to the insulating substrate via a first bonding material using a second bonding material; and
b) sealing a sealed member including the semiconductor element and the laminated substrate using a sealing material, wherein
at least one of the first bonding material and the second bonding material is a silver-containing bonding material, and
the method includes, after the step a) and before the step b),
c) forming a corrosion inhibitor coating layer in contact with a layer of the silver-containing bonding material.

10. The method according to claim 9, wherein
the first bonding material is a silver-containing bonding material, and
the step c) includes forming a corrosion inhibitor coating layer in contact with the layer of the silver-containing bonding material at a joining of the insulating substrate and the conductive plate.

11. The method according to claim 9, wherein
the second bonding material is a silver-containing bonding material, and
the step c) includes forming a corrosion inhibitor coating layer in contact with the layer of the silver-containing bonding material at a joining of the laminated substrate and the semiconductor element.

12. The method according to claim 9, wherein
the step a) includes bonding a heat sink plate to the laminated substrate using a third bonding material, and
the step c) includes forming a corrosion inhibitor coating layer in contact with the layer of the silver-containing bonding material at a joining of the laminated substrate and the heat sink plate.

13. The method according to claim 9, wherein
the step a) includes bonding a conductive connecting member to the semiconductor element using a fourth bonding material,
the fourth bonding material is a silver-containing bonding material, and
the step c) includes forming a corrosion inhibitor coating layer in contact with the layer of the silver-containing bonding material at a joining of the semiconductor element and the conductive connecting member.

14. The method according to claim 9, further comprising:
a wire bonding step after the step a) and before the step b), and performing the step c) after the wire bonding step and before the step b).
